(19) United States
(12) Patent Application Publication
(10) Pub. No.: US 2016/0126231 A1
(43) Pub. Date: May 5, 2016

(54) LEDGE-FREE DISPLAY

(71) Applicant: QUALCOMM MEMS Technologies, Inc., San Diego, CA (US)

(72) Inventors: Denis Endisch, Cupertino, CA (US); Cheonhong Kim, San Diego, CA (US); Wilhelmus Johannes Robertus Van Lier, San Diego, CA (US)

(21) Appl. No.: 14/529,663

(22) Filed: Oct. 31, 2014

(51) Int. Cl. H01L 27/02; G09G 3/34; H01L 27/12

(52) U.S. Cl. CPC H01L 27/0207; H01L 27/124; G09G 3/3466; G09G 2300/0426

(57) ABSTRACT

This disclosure provides systems, methods and apparatus for a ledge-free display. In one aspect, row driver circuits and column driver circuits may be provided from the backside of the display to reduce the size of the bezel around the display and eliminate the need for a bonding ledge for a ledge-free display.

### TECHNICAL FIELD

This disclosure relates to electromechanical systems and devices. More specifically, the disclosure relates to a reduced bezel and ledge-free display, such as an interferometric modulator (IMOD) display.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

In some implementations, one of the plates may be positioned based on an application of voltages to electrodes of the IMOD. The voltages to be applied to the electrodes of the IMOD may be provided by driver circuits implemented on the same substrate (e.g., a glass or other transparent substrate) as the IMODs. For example, the driver circuits can be implemented in the periphery around the IMODs. However, implementing the driver circuits in the periphery around the IMODs may increase the size of the bezel of the display device, making the device larger.

The driver circuits may also be implemented in a chip, bonded on a flex circuit board (chip-on-flex, or COF) which is then bonded to the substrate on which the IMODs are fabricated (flex-on-glass, or FOG). Additionally, the chip implementing the driver circuits may be bonded on the glass (chip-on-glass, or COG). However, a FOG or COG solution may use a “bonding ledge” to bond to the glass and allow for a conductive path between the chip and the IMODs and other components. The bonding ledge may also increase the size of the bezel. Additionally, the bonding ledge may occupy an area on the side of the display which may reduce the size of the display area and cannot accommodate irregular shaped displays (e.g., round, oval, triangular, etc. rather than rectangular or square).

### SUMMARY

The systems, methods and devices of this disclosure each have several innovative aspects, no single one of which is solely responsible for the desirable attributes disclosed herein.

One innovative aspect of the subject matter described in this disclosure can be implemented in device including a display including a display unit associated with one or more transistors at a non-viewing side of the display; a bonding pad on the non-viewing side of the display; an interconnect on the non-viewing side of the display, coupled to the bonding pad; and a via on the non-viewing side of the display, the via coupled to the bonding pad by the interconnect on the non-viewing side of the display, the via further coupled to the interconnect to an internal interconnect of the display.

In some implementations, the internal interconnect can be coupled with the one or more transistors.

In some implementations, the one or more transistors can include a transistor associated with the display unit, wherein the internal interconnect is coupled with a first terminal of the transistor, and the transistor has a second terminal coupled with an electrode of the display unit.

In some implementations, the one or more transistors can include a first row driver transistor associated with a row driver circuit, the first row driver transistor coupled with a second row driver transistor associated with the row driver circuit, wherein the second row driver transistor is behind a second display unit.

In some implementations, the device can include a circuit board bonded to the bonding pad, the circuit board comprising a chip and a conductive path between the chip and the bonding pad.

In some implementations, the display can include a viewing side associated with a substrate.

In some implementations, the display unit can be between the substrate and the one or more transistors.

In some implementations, the bonding pad can be between the circuit board and the one or more transistors.

In some implementations, the device can include a hermetic seal between the bonding pad and the one or more transistors.

In some implementations, the via can be outside of the hermetic seal.

In some implementations, the device can include a processor that is capable of communicating with the display device, the processor being configured to process image data; and a memory device that is capable of communicating with the processor.

In some implementations, the device can include a driver circuit capable of sending at least one signal to the display; and a controller capable of sending at least a portion of the image data to the driver circuit.

In some implementations, the device can include an image source module capable of sending the image data to the processor, wherein the image source module comprises at least one of a receiver, transceiver, and transmitter.

In some implementations, the device can include an input device capable of receiving input data and to communicate the input data to the processor.

Another innovative aspect of the subject matter described in this disclosure can be implemented in a device including a display including an array of display units, each display unit associated with one or more transistors behind the associated display units; an array of bonding pads on a non-viewing side of the display; a plurality of interconnects on the non-viewing side of the display, each of the interconnects coupled to one of the bonding pads; and a plurality of vias on the non-viewing side of the display, each via coupled to one of the interconnects coupled to one of the bonding pads, and each via coupled to an associated internal interconnect of the display.

In some implementations, the device can include a circuit board bonded to the array of bonding pads.

In some implementations, the circuit board includes a chip, and wherein the circuit board includes conductive paths between the chip and the array of bonding pads.

In some implementations, the one or more transistors includes a transistor associated with the display unit, wherein the associated internal interconnect is coupled with a first terminal of the transistor, and the transistor has a second terminal coupled with an electrode of the display unit.

Another innovative aspect of the subject matter described in this disclosure can be implemented in a device including a display including a first display unit; a bonding pad on a non-viewing side of the display; a circuit board coupled with the bonding pad; and an internal interconnect of the display coupled with the bonding pad.

In some implementations, the device can include a first display unit transistor having a first terminal, a second terminal, and a control terminal, wherein the internal interconnect is coupled with the first terminal, and the second terminal is coupled with an electrode of the first display unit.

In some implementations, the device can include a row driver transistor having an output coupled with the control terminal of the control terminal of the first display unit transistor, the row driver transistor and the first display unit transistor both being between the display unit and the bonding pad.

In some implementations, the circuit board can be a chip-on-flex (COF).

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIG. 3 is a graph illustrating movable reflective layer position versus applied voltage for an IMOD display element.

FIG. 4 is a table illustrating various states of an IMOD display element when various common and segment voltages are applied.

FIG. 5A is an illustration of a frame of display data in a three element by three element array of IMOD display elements displaying an image.

FIG. 5B is a timing diagram for common and segment signals that may be used to write data to the display elements illustrated in FIG. 5A.

FIGS. 6A and 6B are schematic exploded partial perspective views of a portion of an electromechanical systems (EMS) package including an array of EMS elements and a backplate.

FIG. 7 is an example of a system block diagram illustrating an electronic device incorporating an IMOD-based display.

FIG. 8 is a circuit schematic of an example of a three-terminal IMOD.

FIG. 9 is an example of a system block diagram illustrating display components of an electronic device.

FIGS. 10A-10D are examples of displays of electronic devices.

FIG. 11A is a circuit schematic of driver circuits for a three-terminal IMOD.

FIG. 11B is a circuit schematic of a driver circuit.

FIG. 12A is an example of a front-view of display components of an electronic device.

FIG. 12B is an example of a back-view of display components of an electronic device.

FIG. 12C is an example of the back-view of FIG. 12B with a chip-on-flex (COF) implementation.

FIG. 13 is an example of a cross-section of the display components of an electronic device.

FIG. 14 is a flow diagram illustrating a method for fabricating a ledge-free display for an electronic device.

FIGS. 15A and 15B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Interferometric modulator (IMOD) displays may include a movable element, such as a mirror, that can be positioned at various points in order to reflect light at a specific wavelength. The movable element may be moved to a particular position based on an application of voltages to electrodes of the IMOD. The voltages provided to the electrodes may be provided based on the operation of driver circuits to provide the appropriate voltages for the display. However, implementing the driver circuits can take up valuable real estate that would otherwise be available to the display or increase the size of the bezel around the display.

The driver circuits may be implemented on the backside, or non-viewing side, of the display on which the IMODs are fabricated. For example, transistors of the driver circuits may be distributed and fabricated on the backside of various IMODs. Additionally, interconnects from inside may be routed to bond pads on the backside. A flex including additional driver circuits may also be used. The flex may be coupled to the bond pads to have the driver circuitry implemented in the chip on the flex to drive various components of the IMOD display from the backside of the display.

Particular implementations of the subject matter described in this disclosure can be implemented to realize one or more of the following potential advantages. Implementing driver circuits on the backside may reduce the size of the bezel around the display of an electronic device, and therefore, provide for a smaller and less bulky electronic device. Additionally, the bonding ledge on the front side can be eliminated, and therefore irregular shaped displays (e.g., round, oval, triangular, etc.) may be accommodated.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

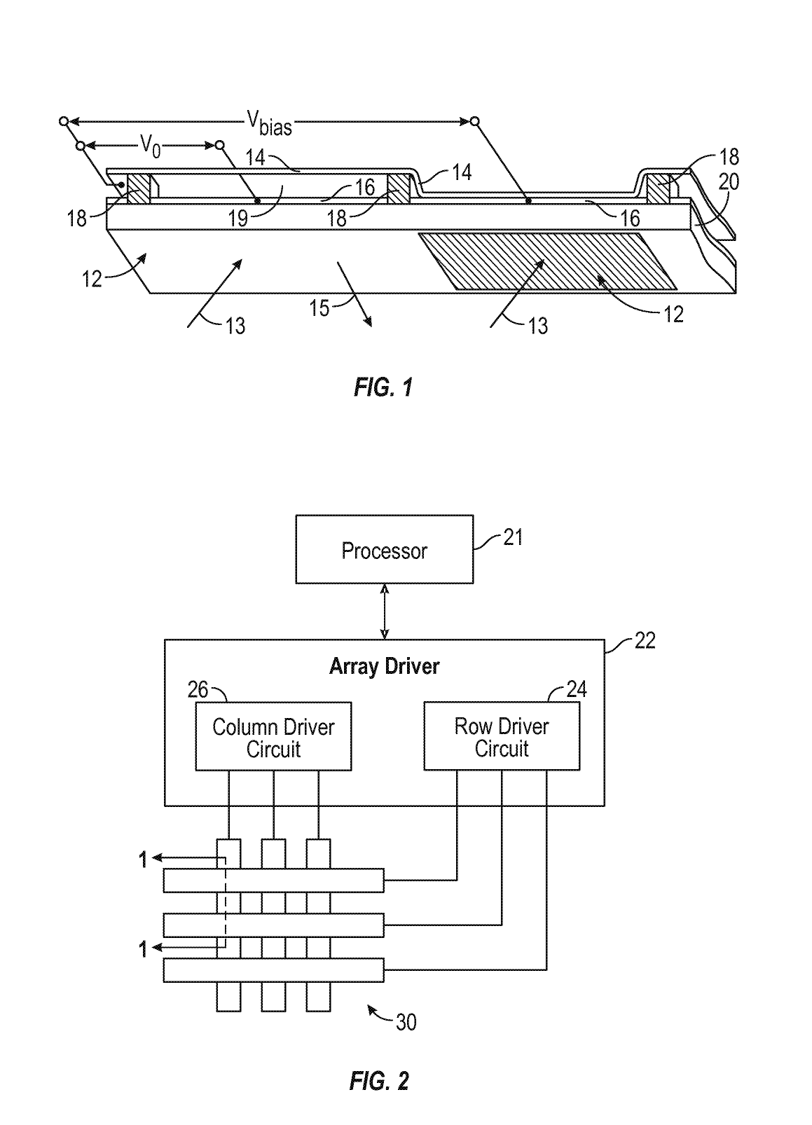

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22.

The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

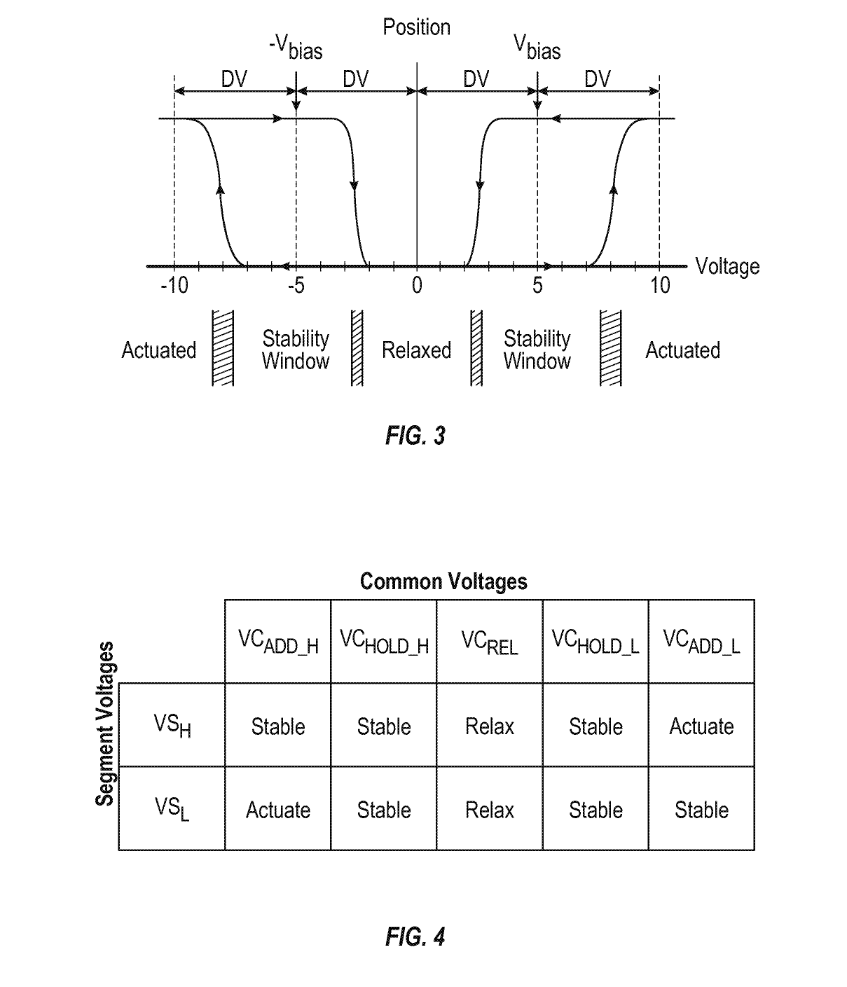

FIG. 3 is a graph illustrating movable reflective layer position versus applied voltage for an IMOD display element. For IMODs, the row/column (i.e., common/segment) write procedure may take advantage of a hysteresis property of the display elements as illustrated in FIG. 3. An IMOD display element may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3-7 volts, in the example of FIG. 3, exists where there is a window of applied voltage within which the element is stable in either the relaxed or actuated state. This is referred to herein as the “hysteresis window” or “stability window.” For a display array 30 having the hysteresis characteristics of FIG. 3, the row/column write procedure can be designed to address one or more rows at a time. Thus, in this example, during the addressing of a given row, display elements that are to be actuated in the addressed row can be exposed to a voltage difference of about 10 volts, and display elements that are to be relaxed can be exposed to a voltage difference of near zero volts. After addressing, the display elements can be exposed to a steady state or bias voltage difference of approximately 5 volts in this example, such that they remain in the previously strobed, or written, state. In this example, after being addressed, each display element sees a potential difference within the “stability window” of about 3-7 volts. This hysteresis property feature enables the IMOD display element design to remain stable in either an actuated or relaxed pre-existing state under the same applied voltage conditions. Since each IMOD display element, whether in the actuated or relaxed state, can serve as a capacitor formed by the fixed and moving reflective layers, this stable state can be held at a steady voltage within the hysteresis window without substantially consuming or losing power. Moreover, essentially little or no current flows into the display element if the applied voltage potential remains substantially fixed.

In some implementations, a frame of an image may be created by applying data signals in the form of “segment” voltages along the set of column electrodes, in accordance with the desired change (if any) to the state of the display elements in a given row. Each row of the array can be addressed in turn, such that the frame is written one row at a time. To write the desired data to the display elements in a first row, segment voltages corresponding to the desired state of the display elements in the first row can be applied on the column electrodes, and a first row pulse in the form of a specific “common” voltage or signal can be applied to the first row electrode. The set of segment voltages can then be changed to correspond to the desired change (if any) to the state of the display elements in the second row, and a second common voltage can be applied to the second row electrode. In some implementations, the display elements in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each display element (that is, the potential difference across each display element or pixel) determines the resulting state of each display element. FIG. 4 is a table illustrating various states of an IMOD display element when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

As illustrated in FIG. 4, when a release voltage VC_{REL} is applied along a common line, all IMOD display elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator display elements or pixels (alternatively referred to as a display element or pixel voltage) can be within the relaxation window (see FIG. 3, also referred to as a release window) both when the high segment voltage VS_{H} and the low segment voltage VS_{L} are applied along the corresponding segment line for that display element.

When a hold voltage is applied on a common line, such as a high hold voltage VC_{HOLD}_{_}_{H} or a low hold voltage VC_{HOLD}_{_}_{L}, the state of the IMOD display element along that common line will remain constant. For example, a relaxed IMOD display element will remain in a relaxed position, and an actuated IMOD display element will remain in an actuated position. The hold voltages can be selected such that the display element voltage will remain within a stability window both when the high segment voltage VS_{H} and the low segment voltage VS_{L} are applied along the corresponding segment line. Thus, the segment voltage swing in this example is the difference between the high VS_{H} and low segment voltage VS_{L}, and is less than the width of either the positive or the negative stability window.

When an addressing, or actuation, voltage is applied on a common line, such as a high addressing voltage VC_{ADD}_{_}_{H} or a low addressing voltage VC_{ADD}_{_}_{L}, data can be selectively written to the modulators along that common line by application of segment voltages along the respective segment lines. The segment voltages may be selected such that actuation is dependent upon the segment voltage applied. When an addressing voltage is applied along a common line, application of one segment voltage will result in a display element voltage within a stability window, causing the display element to remain unactuated. In contrast, application of the other segment voltage will result in a display element voltage beyond the stability window, resulting in actuation of the display element. The particular segment voltage which causes actuation can vary depending upon which addressing voltage is used. In some implementations, when the high addressing voltage VC_{ADD}_{_}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_}_{L} is applied, with high segment voltage VS_{H} causing actuation of the modulator, and low segment voltage VS_{L} having substantially no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

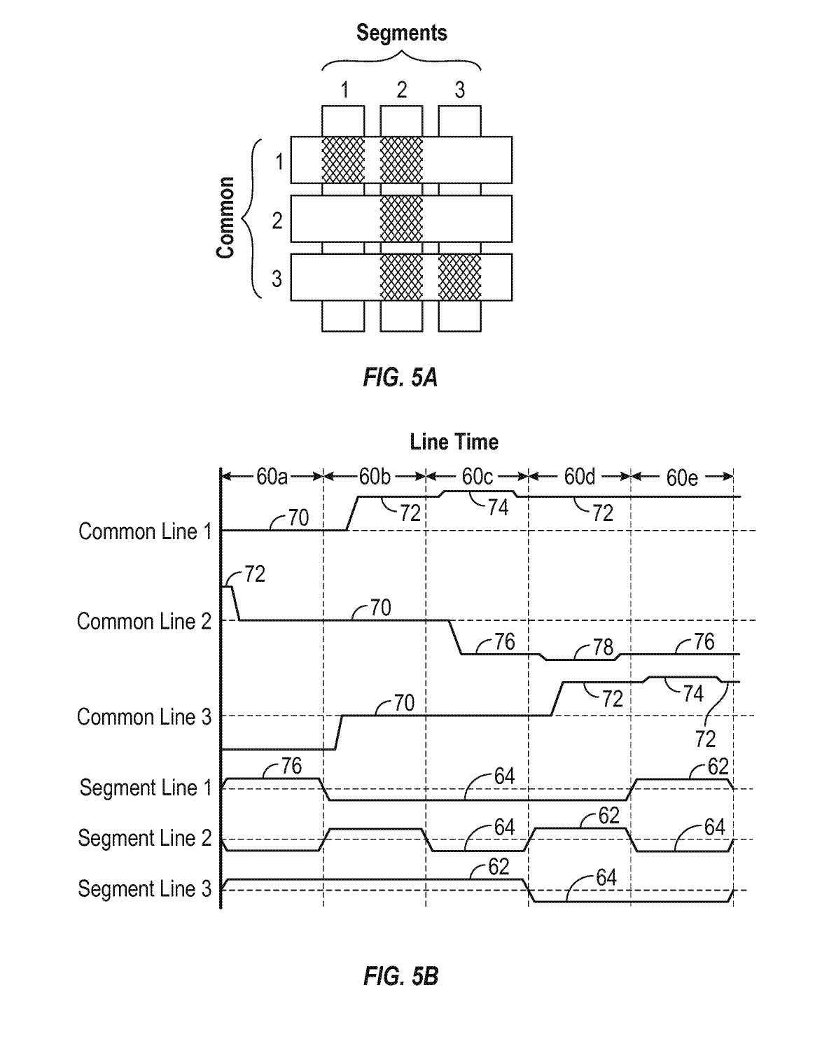

FIG. 5A is an illustration of a frame of display data in a three element by three element array of IMOD display elements displaying an image. FIG. 5B is a timing diagram for common and segment signals that may be used to write data to the display elements illustrated in FIG. 5A. The actuated IMOD display elements in FIG. 5A, shown by darkened checkered patterns, are in a dark-state, i.e., where a substantial portion of the reflected light is outside of the visible spectrum so as to result in a dark appearance to, for example, a viewer. Each of the unactuated IMOD display elements reflect a color corresponding to their interferometric cavity gap heights. Prior to writing the frame illustrated in FIG. 5A, the display elements can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. In some implementations, the segment voltages applied along segment lines 1, 2 and 3 will have no effect on the state of the IMOD display elements, as none of common lines 1, 2 or 3 are being exposed to voltage levels causing actuation during line time 60a (i.e., VC_{REL}−relax and VC_{HOLD}_{_}_{L}−stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the display element voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the display element voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the display element voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state. Then, the voltage on common line 2 transitions back to the low hold voltage 76.

Finally, during the fifth line time 60e, the voltage on common line 1 remains at high hold voltage 72, and the voltage on common line 2 remains at the low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 display element array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the display element voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5A. In some other implementations, voltages applied along common lines or segment lines may vary to account for variations in the actuation and release voltages of different modulators, such as modulators of different colors.

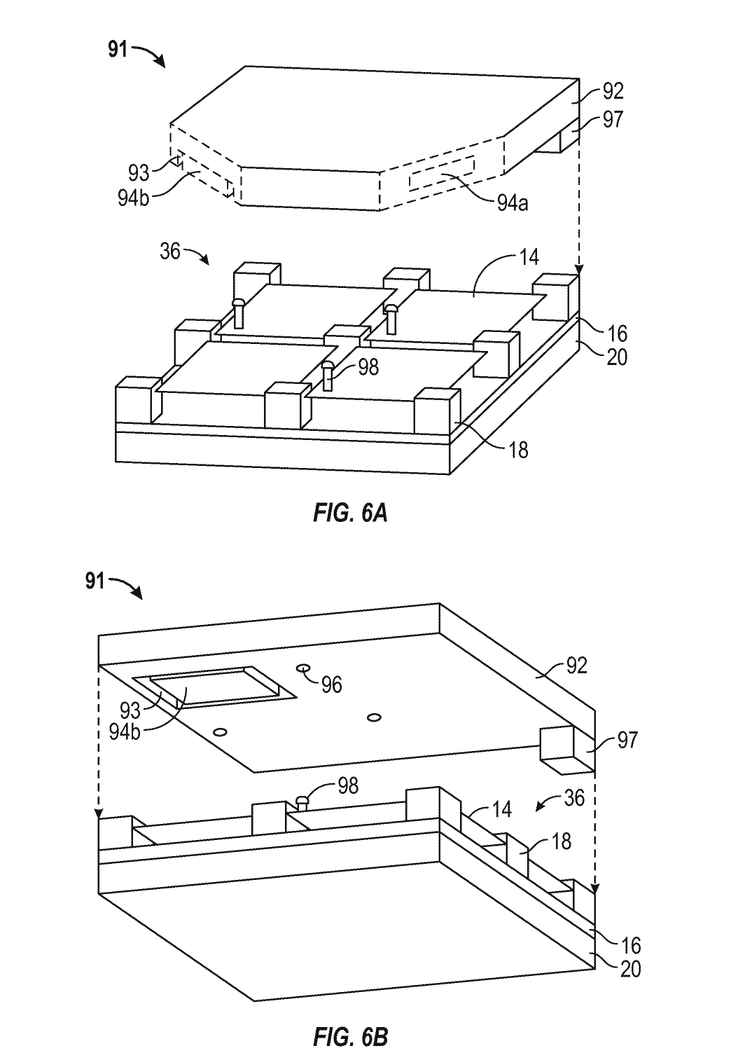

FIGS. 6A and 6B are schematic exploded partial perspective views of a portion of an EMS package 91 including an array 36 of EMS elements and a backplate 92. FIG. 6A is shown with two corners of the backplate 92 cut away to better illustrate certain portions of the backplate 92, while FIG. 6B is shown without the corners cut away. The EMS array 36 can include a substrate 20, support posts 18, and a movable layer 14. In some implementations, the EMS array 36 can include an array of IMOD display elements with one or more optical stack portions 16 on a transparent substrate, and the movable layer 14 can be implemented as a movable reflective layer.

The backplate 92 can be essentially planar or can have at least one contoured surface (e.g., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals, metal foils, Kovar and plated Kovar.

As shown in FIGS. 6A and 6B, the backplate 92 can include one or more backplate components 94a and 94b, which can be partially or wholly embedded in the backplate 92. As can be seen in FIG. 6A, backplate component 94a is embedded in the backplate 92. As can be seen in FIGS. 6A and 6B, backplate component 94b is disposed within a recess 93 formed in a surface of the backplate 92. In some implementations, the backplate components 94a and/or 94b can protrude from a surface of the backplate 92. Although backplate component 94b is disposed on the side of the backplate 92 facing the substrate 20, in other implementations, the backplate components can be disposed on the opposite side of the backplate 92.

The backplate components 94a and/or 94b can include one or more active or passive electrical components, such as transistors, capacitors, inductors, resistors, diodes, switches, and/or integrated circuits (ICs) such as a packaged, standard or discrete IC. Other examples of backplate components that can be used in various implementations include antennas, batteries, and sensors such as electrical, touch, optical, or chemical sensors, or thin-film deposited devices.

In some implementations, the backplate components 94a and/or 94b can be in electrical communication with portions of the EMS array 36. Conductive structures such as traces, bumps, posts, or vias may be formed on one or both of the backplate 92 or the substrate 20 and may contact one another or other conductive components to form electrical connections between the EMS array 36 and the backplate components 94a and/or 94b. For example, FIG. 6B includes one or more conductive vias 96 on the backplate 92 which can be aligned with electrical contacts 98 extending upward from the movable layers 14 within the EMS array 36. In some implementations, the backplate 92 also can include one or more insulating layers that electrically insulate the backplate components 94a and/or 94b from other components of the EMS array 36. In some implementations in which the backplate 92 is formed from vapor-permeable materials, an interior surface of backplate 92 can be coated with a vapor barrier (not shown).

The backplate components 94a and 94b can include one or more desiccants which act to absorb any moisture that may enter the EMS package 91. In some implementations, a desiccant (or other moisture absorbing materials, such as a getter) may be provided separately from any other backplate components, for example as a sheet that is mounted to the backplate 92 (or in a recess formed therein) with adhesive. Alternatively, the desiccant may be integrated into the backplate 92. In some other implementations, the desiccant may be applied directly or indirectly over other backplate components, for example by spray-coating, screen printing, or any other suitable method.

In some implementations, the EMS array 36 and/or the backplate 92 can include mechanical standoffs 97 to maintain a distance between the backplate components and the display elements and thereby prevent mechanical interference between those components. In the implementation illustrated in FIGS. 6A and 6B, the mechanical standoffs 97 are formed as posts protruding from the backplate 92 in alignment with the support posts 18 of the EMS array 36. Alternatively or in addition, mechanical standoffs, such as rails or posts, can be provided along the edges of the EMS package 91.

Although not illustrated in FIGS. 6A and 6B, a seal can be provided which partially or completely encircles the EMS array 36. Together with the backplate 92 and the substrate 20, the seal can form a protective cavity enclosing the EMS array 36. The seal may be a semi-hermetic seal, such as a conventional epoxy-based adhesive. In some other implementations, the seal may be a hermetic seal, such as a thin film metal weld or a glass frit. In some other implementations, the seal may include polyisobutylene (PIB), polyurethane, liquid spin-on glass, solder, polymers, plastics, or other materials. In some implementations, a reinforced sealant can be used to form mechanical standoffs.

In alternate implementations, a seal ring may include an extension of either one or both of the backplate 92 or the substrate 20. For example, the seal ring may include a mechanical extension (not shown) of the backplate 92. In some implementations, the seal ring may include a separate member, such as an O-ring or other annular member.

In some implementations, the EMS array 36 and the backplate 92 are separately formed before being attached or coupled together. For example, the edge of the substrate 20 can be attached and sealed to the edge of the backplate 92 as discussed above. Alternatively, the EMS array 36 and the backplate 92 can be formed and joined together as the EMS package 91. In some other implementations, the EMS package 91 can be fabricated in any other suitable manner, such as by forming components of the backplate 92 over the EMS array 36 by deposition.

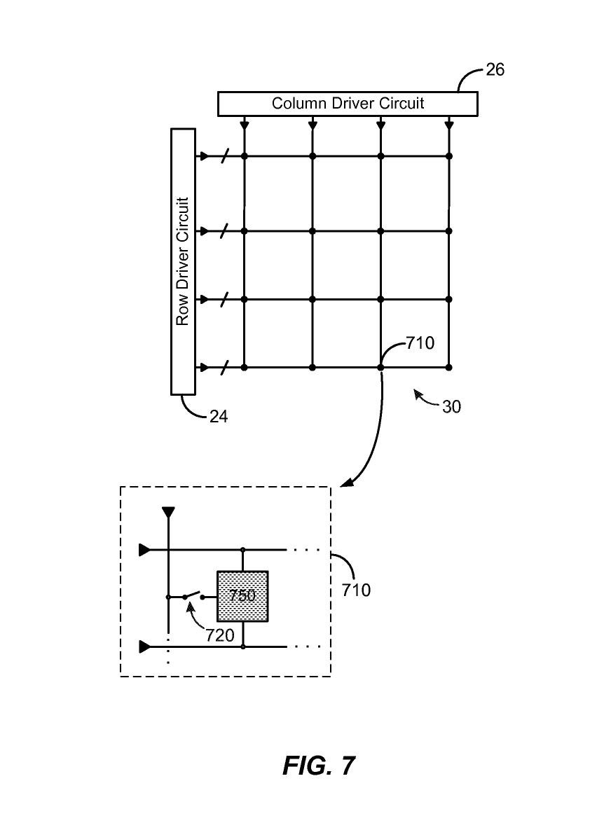

FIG. 7 is an example of a system block diagram illustrating an electronic device incorporating an IMOD-based display. FIG. 7 depicts an implementation of row driver circuit 24 and column driver circuit 26 of array driver 22 of FIG. 2 that provide signals to display array or panel 30, as previously discussed.

The implementation of display module 710 in display array 30 may include a variety of different designs. As an example, display module 710 in the fourth row may include switch 720 and display unit 750. Display module 710 may be provided a row signal, reset signal, bias signal, and a common signal from row driver circuit 24. Display module 710 may also be provided a data signal from column driver circuit 26. In some implementations, display unit 750 may be coupled with switch 720, such as a transistor with its gate coupled to the row signal and its drain coupled with the column signal. Each display unit 750 may include an IMOD display element as a pixel.

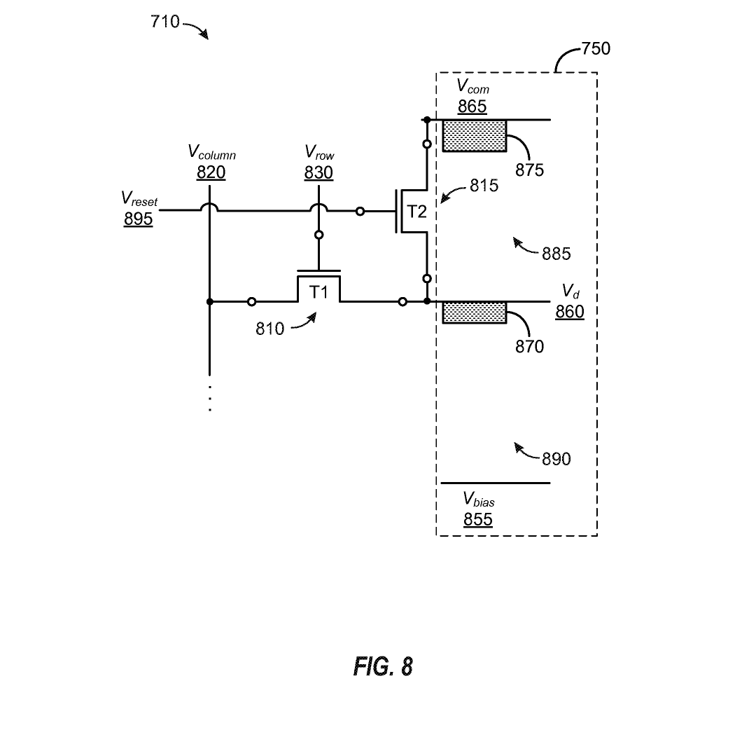

Some IMODs are three-terminal devices that use a variety of signals. FIG. 8 is a circuit schematic of an example of a three-terminal IMOD. In the example of FIG. 8, display module 710 includes display unit 750 (e.g., an IMOD). The circuit of FIG. 8 also includes switch 720 of FIG. 7 implemented as an n-type metal-oxide-semiconductor (NMOS) transistor T1 810. The gate of transistor T1 810 is coupled to V_{row} 830 (i.e., a control terminal of transistor T1 810 is coupled to V_{row} 830 providing a row select signal), which may be provided a voltage by row driver circuit 24 of FIG. 7. Transistor T1 810 is also coupled to V_{column} 820, which may be provided a voltage by column driver circuit 26 of FIG. 7. If V_{row} 830 (providing a row select signal) is biased to turn transistor T1 810 on, the voltage on V_{column} 820 may be applied to V_{d} electrode 860. The circuit of FIG. 8 also includes another switch implemented as an NMOS transistor T2 815. The gate (or control) of transistor T2 815 is coupled with Vᵣₑₛₑₜ 895. The other two terminals of transistor T2 815 are coupled with V_{com} electrode 865 and V_{d} electrode 860. When transistor T2 815 is biased to turn on (e.g., by a voltage of a reset signal on Vᵣₑₛₑₜ 895 applied to the gate of transistor T2 815), V_{com} electrode 865 and V_{d} electrode 860 may be shorted together.

Display unit 750 may be a three-terminal IMOD including three terminals or electrodes: V_{bias} electrode 855, V_{d} electrode 860, and V_{com} electrode 865. Display unit 750 may also include movable element 870 and dielectric 875. Movable element 870 may include a mirror, as previously discussed. Movable element 870 may be coupled with V_{d} electrode 860. Additionally, air gap 890 may be between V_{bias} electrode 855 and V_{d} electrode 860. Air gap 885 may be between V_{d} electrode 860 and V_{com} electrode 865. In some implementations, display unit 750 may also include one or more capacitors. For example, one or more capacitors can be coupled between V_{d} electrode 860 and V_{com} electrode 865 and/or between V_{bias} electrode 855 and V_{d} electrode 860.

Movable element 870 may be positioned at various points between V_{bias} electrode 855 and V_{com} electrode 865 to reflect light at a specific wavelength. In particular, voltages applied to V_{bias} electrode 855, V_{d} electrode 860, and V_{com} electrode 865 may determine the position of movable element 870.

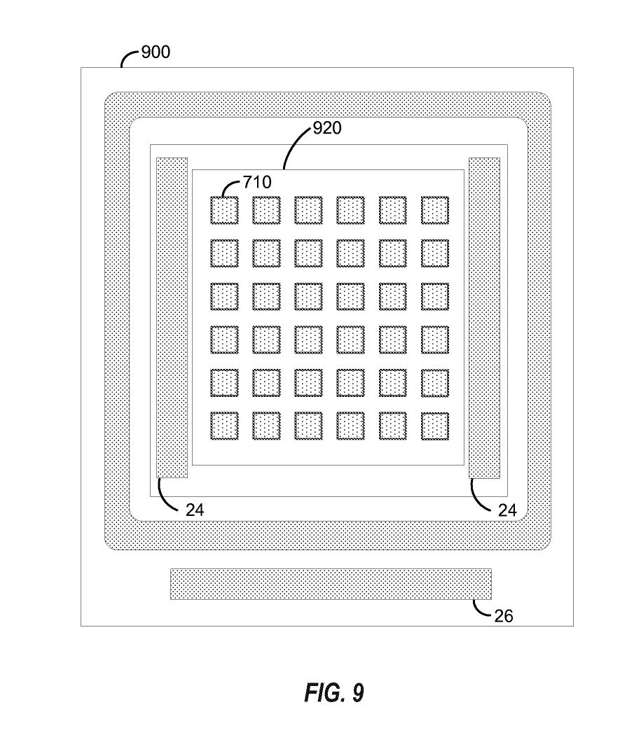

FIG. 9 is an example of a system block diagram illustrating display components of an electronic device. In FIG. 9, display 900 includes display area 920 including display modules 710. Display modules 710 of display area 920 may be fabricated on a substrate (e.g., a transparent substrate such as glass). Display area 920 may include row driver circuits 24 also fabricated (e.g., with indium gallium zinc oxide (IGZO) process technology) on the glass substrate. In FIG. 9, column driver circuit 26 may be implemented in a flex-on-glass (FOG) or chip-on-glass (COG) implementation with the driver circuitry implemented with conventional complementary metal-oxide-semiconductor (CMOS) process technology. The driver circuits may drive various components of display modules 710.

However, display 900 of FIG. 9 may have a large bezel around display area 920 due to the size of row driver circuit 24 and column driver circuit 26 in the periphery around display area 920. That is, display 900 may accommodate driver circuitry and interconnect by implementing them around display area 920 and underneath a bezel of display 900. A large bezel may increase the size of the display device. Additionally, if column driver circuit 26 is implemented with FOG or COG, a “bonding ledge” may be needed to hold the FOG or COG and to further provide a conductive path between the components fabricated on the glass substrate and the driver circuits in the FOG or COG. The bonding ledge may occupy an area on the side of the display which may reduce the size of display area 920 and may not accommodate non-rectangular shaped displays, such as round, oval, triangular, or other shaped displays.

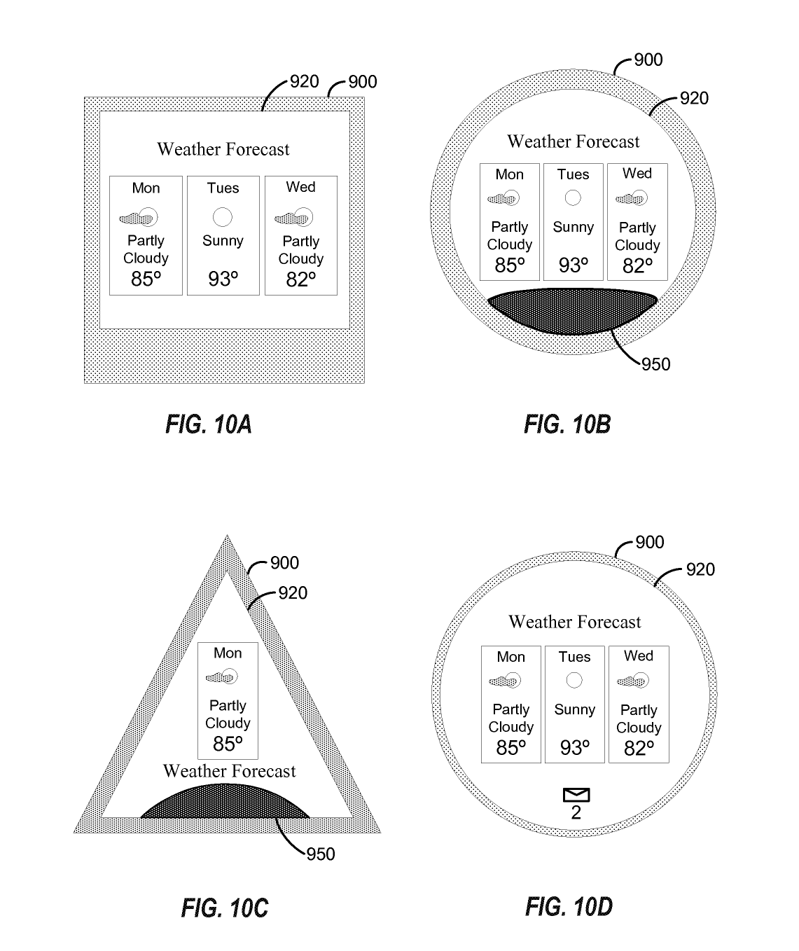

FIGS. 10A-10D are examples of displays of electronic devices. FIG. 10A shows display 900 implemented with a rectangular-shaped display area 920. The bezel around display area 920 may be large to accommodate row driver circuit 24 and column driver circuit 26, as previously discussed. FIG. 10B shows display 900 with a partially circular-shaped display area 920. In FIG. 10B, ledge 950 (i.e., the bonding ledge, as previously discussed) occupies a portion of display 900 that would otherwise be available for display area 920. Accordingly, a true circular shape may not be available for display area 920 because a portion along an edge may be used for ledge 950. FIG. 10C shows display 900 with a partially triangular-shaped display area 920. As in the partially circular-shaped display area 920 in FIG. 10B, the partially triangular-shaped display area 920 also includes a portion used for ledge 950. Because ledge 950 occupies space that would be otherwise available for display area 920, display area 920 is smaller and conveys less information.

By contrast, FIG. 10D provides an example of display 900 with a reduced bezel. Additionally, display 900 of FIG. 10D does not include ledge 950, and therefore, provides a true circular-shaped display area 920 and may convey more information than the implementation of FIG. 10B.

Display 900 having a true circular-shaped (or other-shaped) display area 920 without a ledge and a reduced bezel, as in FIG. 10D, may be accommodated by having row driver circuit 24 implemented on the backside of display 900. For example, transistors of row driver circuit 24 may be distributed and fabricated behind various display units 750 of display modules 710. Additionally, interconnects from inside may be routed to bond pads on the backside of display 900. A flex with a chip implementing column driver circuit 26 may be coupled with the bond pads to drive various components of the display modules 710 from the backside. As such, the bezel of display 900 may be reduced and ledge 950 may not be needed.

Additionally, display 900 would be able to accommodate a rim with additional information visible from the side of display 900. For example, if display 900 is a round display which is curved toward the edges (e.g., shaped like an inverted bowl), the edges can allow for additional information to be displayed.

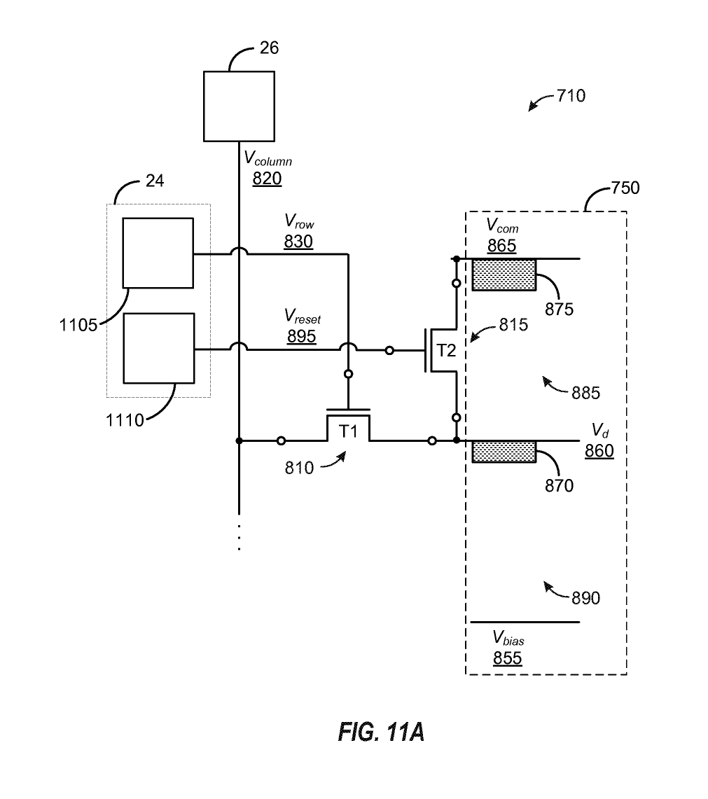

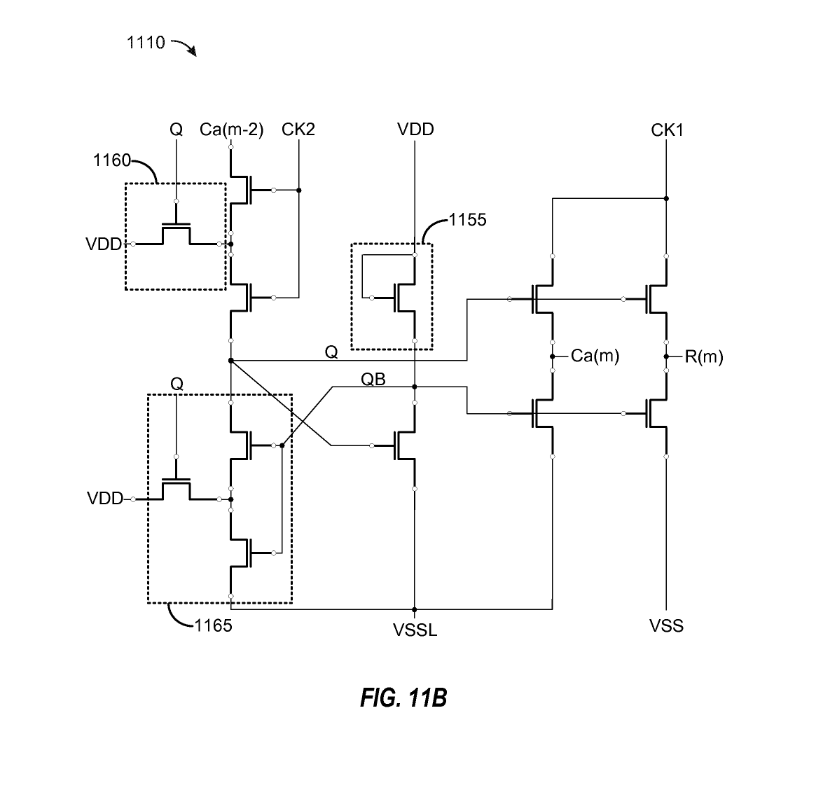

FIG. 11A is a circuit schematic of driver circuits for a three-terminal IMOD. In FIG. 11A, row driver circuit 24 includes row driver circuit 1105 providing V_{row} 830 (i.e., driving the gate of transistor T1 810) and row driver circuit 1110 providing Vᵣₑₛₑₜ 895 (i.e., driving the gate of transistor T2 815). Column driver circuit 26 may provide V_{column} 820 (i.e., driving one of the inputs of transistor T1 810). In some implementations, V_{com} electrode 865 and V_{bias} electrode 855 may also be driven by a driver circuit.

In some implementations, transistors T1 810 and T2 815 of display module 710 may be fabricated on the backside of display area 920. That is, transistors T1 810 and T2 815 may be fabricated behind display unit 750 (e.g., an IMOD display element). Moreover, row driver circuits 1105 and 1110 of row driver circuit 24 may also be fabricated on the backside of display 900. Additionally, column driver circuit 26 may be implemented in a chip on a flex. The chip can include column driver circuit 26. The flex with the chip may also be bonded on the backside of display 900. Accordingly, row driver circuit 24 and column driver circuit 26 may be on the backside of display 900, and therefore, reduce the size of the bezel around display area 920 and eliminate the need for a ledge for column driver circuit 26.

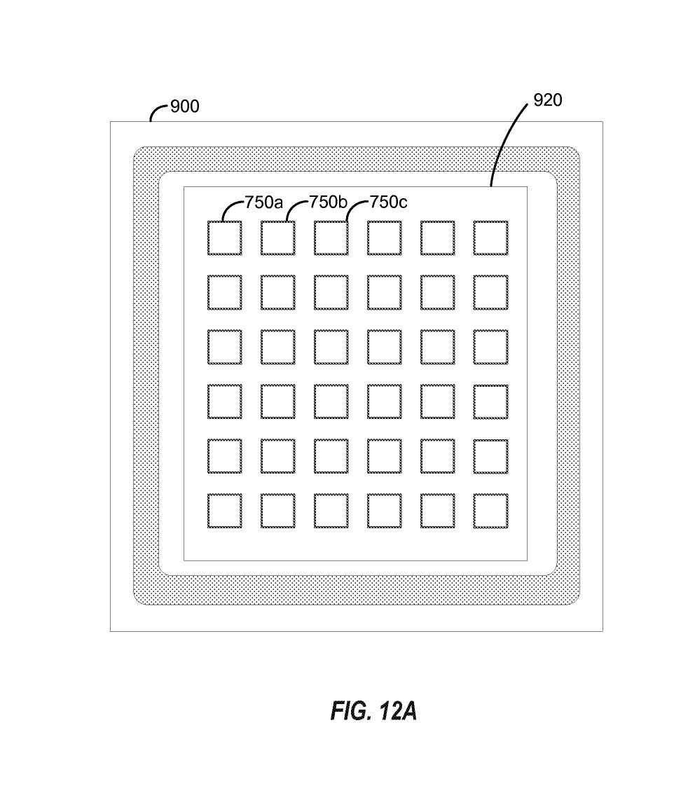

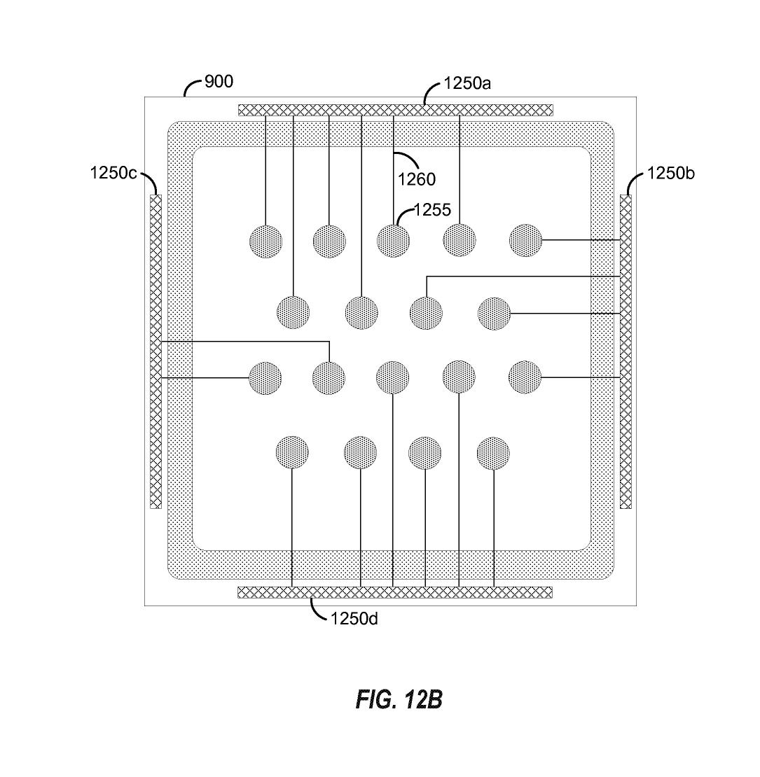

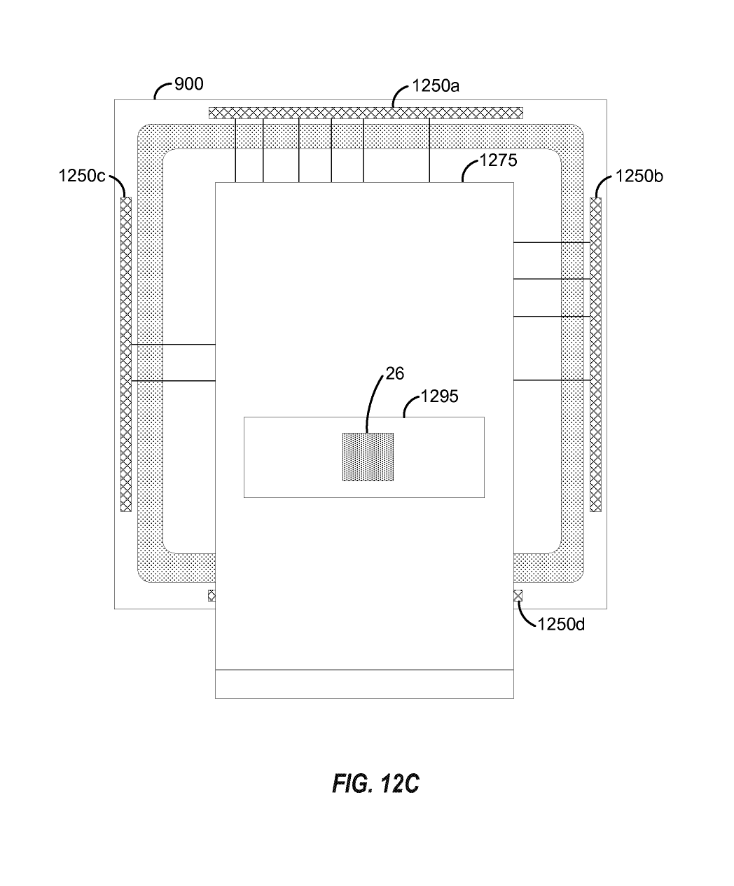

For example, FIG. 11B is a circuit schematic of a driver circuit. Row driver circuit 1110 in FIG. 11B may provide Vᵣₑₛₑₜ 895, as previously discussed. The example of row driver circuit 1110 in FIG. 11B includes 12 NMOS transistors that may be distributed among the backside of display 900. For example, portion 1160 of row driver circuit 1110 may include a single transistor. Portion 1155 may also include another single transistor. Portion 1165 may include three other transistors. Each of portions 1155, 1160, and 1165 may be distributed behind different display units 750 on the backside of display 900. For example, FIG. 12A is an example of a front-view of display components of an electronic device. Portion 1155 may be fabricated behind display unit 750a. That is, the transistor in portion 1155 may be fabricated on the backside of display 900, and in particular behind display unit 750a. Portion 1160 may be fabricated behind display unit 750b. Portion 1165 may be fabricated behind display unit 750c. Accordingly, the transistors of row driver circuit 1100 in FIG. 11B may be distributed behind a variety of display units 750 of display area 920. Though distributed behind a variety of display units 750, the interconnect between the transistors of row driver circuit 1100, inputs, and outputs may still be implemented such that the functionality of row driver circuit 1100 is still provided even though the transistors may be fabricated behind a variety of different display units 750.

Since row driver circuit 1100 is fabricated on the backside of display 900, access (e.g., to provide data inputs or power supplies) to transistors of row driver circuit 1100 may also be from the backside. FIG. 12B is an example of a back-view of display components of an electronic device. In FIG. 12B, bonding pads 1255 may also be distributed on the backside of display 900. Bonding pads 1255 may be coupled with via areas 1250a-1250d by interconnect 1260. Via areas 1250a-1250d may include vias providing access to internal interconnect within display 900 to drive components of row driver circuit 24 and/or components of display module 710 (e.g., transistor T1 810 and transistor T2 815). As an example, one bonding pad 1255 may provide access through interconnect 1260 to a via coupled with internal interconnect for providing power supply VDD of row driver circuit 1110 of FIG. 11B.

A connection between the bonding pads 1255 and a flexible printed circuit (FPC) (e.g., flex 1275 in FIG. 12B as described below) may be made from a variety of materials. For example, low temperature solder, organic conductive materials, conductive epoxy, anisotropic conductive film, and other types of materials may be used.

Four via areas 1250a-1250d are shown in FIG. 12B. However, in other implementations, more or less via areas may be provided. For example, a single via area may be provided with all bonding pads 1255 coupled to vias in the single via area by interconnects 1260.

Additionally, column driver circuit 26 may also be provided from the backside. FIG. 12C is an example of the back-view of FIG. 12B with a flex circuit board implementation. FIG. 12C is also a back-view of display 900. In FIG. 12C, flex 1275 may be a circuit board that includes chip 1295 implementing column driver circuit 26. The flex may be conductively coupled with bonding pads 1255, providing a conductive path between column driver circuit 26 (or chip 1295) and components of display module 710. For example, column driver circuit 26 may provide V_{column} 820 for each column of display modules 710 in display area 920. As such, each column of display modules 710 may be associated with a bonding pad 1255 that is driven by column driver circuit 26. The bonding pads 1255 may include access to a particular column through a via in via areas 1250a-1250d to provide V_{column} 820 for the column of display modules 710. Additionally, inputs (e.g., data or power supplies) for row driver circuit 24 may also be provided by chip 1295 and provided through bonding pads 1255 coupled with row driver circuit 24 implemented on the backside of display unit 750. Accordingly, contact to the components on the backside of display 900 may be available through the backside, and therefore, the size of the bezel may be reduced and the bonding ledge on the frontside, or viewing side, eliminated.

Though FIG. 12C shows a single chip 1295 on flex 1275, in other implementations, multiple chips may be on flex 1275. Additionally, other types of components may be on flex 1275. For example, discrete components such as capacitors, resistors, transistors, diodes, etc. may also be on flex 1275.

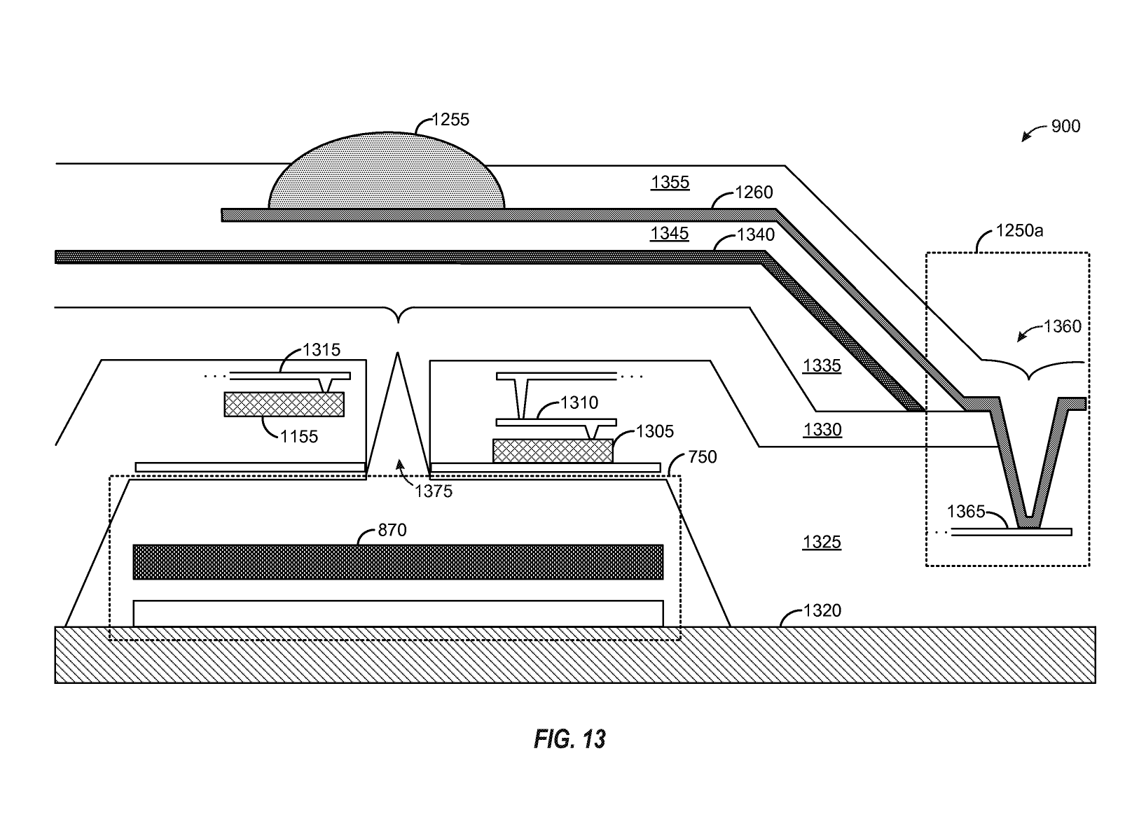

FIG. 13 is an example of a cross-section of the display components of an electronic device. In particular, FIG. 13 shows a simplified cross-section of bonding pad 1255, display unit 750, and via area 1250a of display 900.

In FIG. 13, display 900 may include multiple layers that may be fabricated upon substrate 1320, which may be towards the frontside of display 900. For example, display unit 750 may be fabricated on substrate 1320 and a cavity including movable element 870 may be formed within dielectric 1325. Dielectric 1325 may include more than one layer and may be selected from a variety of materials such as CVD deposited silicon dioxide, other commonly used oxides, or spin-on dielectrics. Generally, substrate 1320 and display unit 750 may be in or on the frontside, or viewing side, of display 900 (i.e., the side viewed when display 900 is being watched by a user). The other components may be in or on the backside, or non-viewing side of display 900 (i.e., the side not in view when display 900 is being watched by a user). For example, portion 1155 (i.e., a transistor from row driver circuit 1100) may also be fabricated within dielectric 1325 and behind display unit 750. Portion 1155 may also be coupled with row driver interconnect 1315 which may route to other portions of row driver circuit 1155 (e.g., other portions on the backside of other display units 750) to implement row driver circuit 1100. Additionally, row driver interconnect 1315 may route to other components, as discussed below.

Display module transistors 1305 may also be fabricated within dielectric 1325 and behind display unit 750. Display module transistors 1305 may include transistors T1 810 and T2 815 for display unit 750 in FIG. 13. Display module transistors 1305 may also be coupled with display module transistors interconnect 1310 to route to other components (e.g., portion 1155 or an electrode of display unit 750, such as V_{com} electrode 865 or V_{d} electrode 860).

Row driver interconnect 1315 and display module transistors interconnect 1310 may provide conductive paths to components within row driver 24 and display module 710 (i.e., the same display module 710 including display unit 750 that the respective portion 1155 or display module transistors 1355 are fabricated behind, or a portion 1155 or display module transistors 1355 behind another display unit 750). For example, as previously discussed, row driver interconnect 1315 may couple the various portions of row driver circuit 1100 together. Additionally, row driver interconnect 1315 may route to components of display module 710, such as display module transistors 1305 or terminals of display unit 750. As an example, row driver interconnect 1315 may route to display module transistors 1305 of the same display unit 750 they are both fabricated behind. In another example, row driver interconnect 1315 may route to display module transistors 1305 behind a different display unit 750. Additionally, in FIG. 13, row driver interconnect 1315 and display module transistors interconnect 1310 may route to interconnect 1365 (i.e., an internal interconnect of display 900) and via 1360 in via area 1250a, which is coupled with bonding pad 1255 with interconnect 1260. Bonding pad 1255 may be coupled with chip 1295 (e.g., implementing column driver circuit 26 or providing inputs to row driver circuit 24) on a flex, as previously discussed. Accordingly, via area 1250a in FIG. 13 may include via 1360 providing a conductive path from bonding pad 1255 to interconnect 1365, which may route, for example, to a transistor of row driver circuit 1100 (e.g., portion 1155) or display module transistors 1305 (e.g., transistors T1 810 or T2 815).

In FIG. 13, portion 1155 and display module transistors 1305 may be fabricated on two different levels (i.e., portion 1155 is fabricated at a layer above display module transistors 1305). However, in other implementations, portion 1155 and display module transistors 1305 may be fabricated on the same level.

Layers 1330, 1335, 1345, and 1355 may be deposited on top of dielectric 1325 to provide layers that can be planarized (e.g., with chemical-mechanical planarizing or polishing, or with deposition of a liquid or flowable material such as spin-on glass, spin-on polymer, or resist which may fill gaps in the underlying layer and provide a new, planarized layer) for a smooth surface as well as provide an insulating layer between conductive layers. In some implementations, layer 1330 (i.e., the layer just above dielectric 1325) may additionally serve to “pinch off,” or close, release hole 1375 to seal display unit 750. Release hole 1375, at the center and back of display unit 750, may initially be used during the fabrication of display unit 750. However, in some implementations, release hole 1375 may be better closed off with a material that has otherwise poor planarization properties. Accordingly, layer 1330 may be a material which provides better closing of release hole 1375, but poor planarization. As such, layer 1335 (i.e., the layer above layer 1330) may provide the planarization. Layers 1335, 1345, and 1355 may be selected from a variety of materials, such as TEOS based silicon dioxide, which has good planarization properties for a CVD based material, or SU-8, a photoresist which may have a thickness greater than 100 micrometers (μm) and can be left in place following deposition and patterning. Moreover, having a thicker dielectric stack may provide more mechanical stability for display unit 750.

Hermetic seal 1340 may be a metal layer (e.g., aluminum) providing a hermetic seal for preventing moisture or other contamination from interfering with the components of display unit 750. In other implementations, hermetic seal 1340 may be a dielectric with low permeability, such as a nitride. Additionally, hermetic seal 1340 may include multiple layers (i.e., a multilayer hermetic seal). In some implementations, multiple hermetic seal layers may be separated by planarization layers to allow for stress relaxation, reduction in the likelihood of cracking of the hermetic seal layers, and to encapsulate the seal layers. The multiple hermetic seal layers may also be implemented similar to the Barix® multiple seal layer used in organic light-emitting diodes (OLEDs). In FIG. 13, via 1360 is etched from the backside of display 900 (i.e., before deposition of layer 1355) outside of hermetic seal 1340 such that contact may be made with interconnect 1365.

In some implementations, the layers portrayed in FIG. 13 may include an arrangement of thick and thin layers with the thicker layers being more rigid than the thinner layers to resist deformation or flexibility. Generally, the cost of thicker layers is lower for upper layers (i.e., layers away from substrate 1320). Accordingly, thicker layers may be positioned farther away from display unit 750 and thinner layers may be closer to display unit 750 than the thicker layers. For example, layers 1355 and 1345 may be thicker than layer 1335. As another example, layer 1330 may be thinner than layers 1335, 1345, and 1355. In another example, layer 1330 may be less than 1 micrometer (μm) and layers 1335, 1345, and 1355 may each be more than 1 μm.

In some implementations, one or more of the metal layers portrayed in FIG. 13 may be used as a ground plane to reduce cross-talk between display unit 750 and the circuitry implemented on the backside. For example, any of the hermetic seals may be used as a ground plane.

In the simplified example of FIG. 13, a single display unit 750 is shown beneath bonding pad 1255. However, multiple display units 750 may be beneath each bonding pad 1255. Having multiple display units 750 beneath each bonding pad 1255 may distribute mechanical forces (e.g., the pressure from bonding flex 1275 to the backside of display area 920, as well as pulling and shearing forces) among multiple display units 750. Additionally, layers 1330, 1335, 1345, and 1355 may act as buffering layers between bonding pad 1255 and display unit 750. For example, a thick polymer as a layer may “cushion” localized pressure such that damage to display unit 750 may be avoided.

In some implementations, multiple “copies” of the same transistor of row driver circuit 24 may be fabricated behind any number of display units 750. For example, in FIG. 11B, portion 1160 includes a single transistor. Rather than fabricating the single transistor behind a single display unit 750, multiple copies of the transistor may be fabricated behind multiple different display units 750. The multiple copies may be coupled in parallel to provide the same functionality as the single transistor in portion 1160. Such an implementation may be beneficial if the transistor is of a larger size in order to provide a particular current load, but not enough space exists behind display unit 750 to fabricate the larger sized transistor. Instead, multiple smaller transistors may be provided in parallel such that they collectively may be able to provide the appropriate current load. Moreover, having multiple transistors may provide redundancy. For example, if one of the multiple transistors is defective, it may be bypassed (e.g., its inputs and/or outputs may be disconnected from the rest of the circuit) and the remaining transistors in the multiple transistors can still provide the proper functionality.

In some implementations, interconnect 1260 underneath bonding pad 1255 may extend beyond bonding pad 1255 on all sides to avoid stress concentration points at the edges of bonding pad 1255. Additionally, a higher thickness of bonding pad 1255 may also provide further protection from mechanical forces such as stress.

In some implementations, solid “dummy” display units may be placed in display area 920. The dummy display units may be used in display area 920 to add additional mechanical support. For example, a dummy display unit may not include release hole 1375 so that there is no cavity providing air gaps for movable element 870 to be positioned within. Rather, the entire cavity may be filled with sacrificial material. During the fabrication of display units 750, the sacrificial material may be removed via release hole 1375, but since the dummy display units may not include release hole 1375, the sacrificial material may remain, and therefore, provide a solid dummy display unit. In some implementations, the dummy display units may have a higher thickness than display units 750 because a black mask layer may cover the entire area above the dummy display unit, and therefore, increase the thickness of all of the layers above it. Multiple dummy display units may be provided under each bonding pad 1255 (e.g., three dummy display units under each bonding pad 1255).

As previously discussed, before the deposition of layer 1330 to seal display unit 750, release hole 1375 may allow access through dielectric 1325 to display unit 750. Initially, release hole 1375, at the center and back of display unit 750, may be used during the fabrication of display unit 750 to remove sacrificial material within display unit 750 such that movable element 870 may be positioned within a cavity created from the removal of the sacrificial material. In particular, when release hole 1375 is not yet closed, an etchant may be used etch away the sacrificial material around movable element 870. Accordingly, the open release hole 1375 may be used to get etchant into display unit 750 and to remove the sacrificial material out of display unit 750. Afterwards, release hole 1375 may be closed as in FIG. 13. For example, physical vapor deposition (PVD) may be used to deposit layer 1330 which may be used to close off release hole 1375. The deposition of layer 1330 may be done such that none or a mirror amount of the material used in layer 1330 is deposited into the cavity formed within display unit 750 and/or upon movable element 870. This may be performed by controlling the angle of the deposition material as well as having a higher aspect ratio for release hole 1375 (e.g., a 3:1 or higher aspect ratio for the height to width of release hole 1375 within dielectric 1325). In some implementations, release hole 1375 may be at a different location and/or have different geometry, such as an opening to the side of the display unit 750 instead of the center top, thus preventing the PVD material from entering the display cavity.

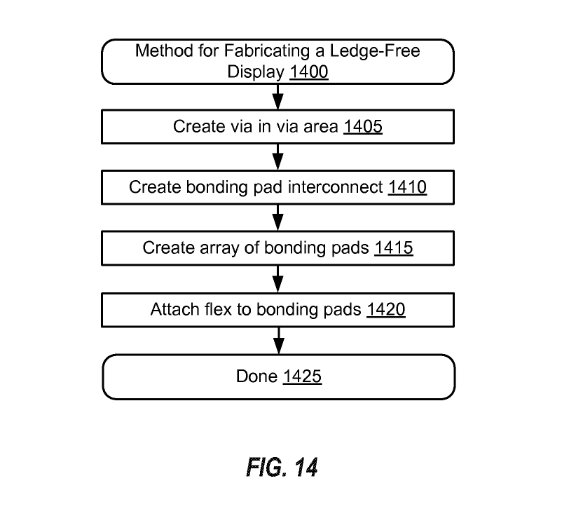

FIG. 14 is a flow diagram illustrating a method for fabricating a ledge-free display for an electronic device. In method 1400, at block 1405, a via in a via area may be fabricated. For example, via 1360 in via area 1250a may be etched in dielectric 1325 to interconnect 1365. At block 1410, bonding pad interconnect may be created. For example, interconnect 1260 may be created. At block 1415, an array of bond pads may be created. For example, bonding pads 1255 may be created. At block 1420, a flex may be attached to the bonding pads. For example, flex 1275 may be attached to the array of bonding pads 1255. The method ends at block 1425.

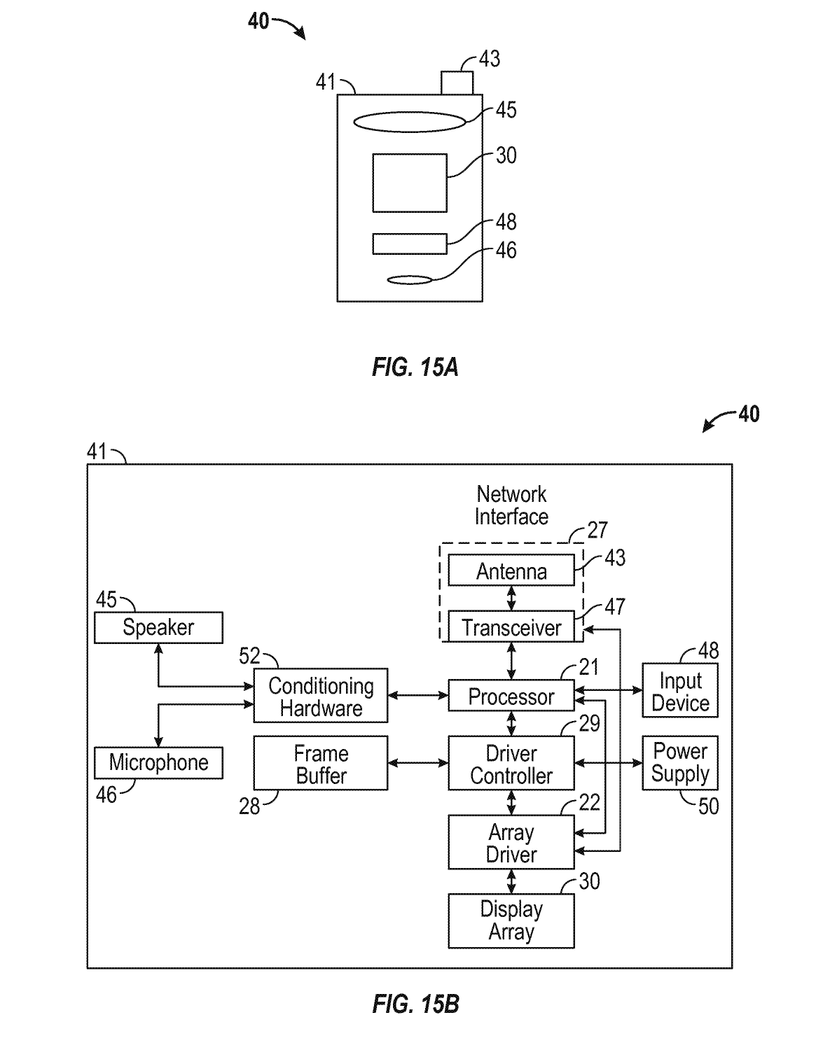

FIGS. 15A and 15B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 15A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 15A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
a display including a display unit associated with one or more transistors at a non-viewing side of the display;
a bonding pad on the non-viewing side of the display;
an interconnect on the non-viewing side of the display, coupled to the bonding pad; and
a via on the non-viewing side of the display, the via coupled to the bonding pad by the interconnect on the non-viewing side of the display, the via further coupled to the interconnect to an internal interconnect of the display.

2. The device of claim 1, wherein the internal interconnect is coupled with the one or more transistors.

3. The device of claim 2, wherein the one or more transistors includes a transistor associated with the display unit, wherein the internal interconnect is coupled with a first terminal of the transistor, and the transistor has a second terminal coupled with an electrode of the display unit.

4. The device of claim 2, wherein the one or more transistors includes a first row driver transistor associated with a row driver circuit, the first row driver transistor coupled with a second row driver transistor associated with the row driver circuit, wherein the second row driver transistor is behind a second display unit.

5. The device of claim 1, further comprising:
a circuit board bonded to the bonding pad, the circuit board comprising a chip and a conductive path between the chip and the bonding pad.

6. The device of claim 1, wherein the display includes a viewing side associated with a substrate.

7. The device of claim 6, wherein the display unit is between the substrate and the one or more transistors.

8. The device of claim 7, wherein the bonding pad is between the circuit board and the one or more transistors.

9. The device of claim 8, further comprising:
a hermetic seal between the bonding pad and the one or more transistors.

10. The device of claim 9, wherein the via is outside of the hermetic seal.

11. The device of claim 1, further comprising:
a processor that is capable of communicating with the display device, the processor being configured to process image data; and
a memory device that is capable of communicating with the processor.

12. The device of claim 11, further comprising:
a driver circuit capable of sending at least one signal to the display; and
a controller capable of sending at least a portion of the image data to the driver circuit.

13. The device of claim 11, further comprising:
an image source module capable of sending the image data to the processor, wherein the image source module comprises at least one of a receiver, transceiver, and transmitter.

14. The device of claim 11, further comprising:
an input device capable of receiving input data and to communicate the input data to the processor.

15. A device comprising:
a display including an array of display units, each display unit associated with one or more transistors behind the associated display units;
an array of bonding pads on a non-viewing side of the display;
a plurality of interconnects on the non-viewing side of the display, each of the interconnects coupled to one of the bonding pads; and
a plurality of vias on the non-viewing side of the display, each via coupled to one of the interconnects coupled to one of the bonding pads, and each via coupled to an associated internal interconnect of the display.

16. The device of claim 15, further comprising:
a circuit board bonded to the array of bonding pads.

17. The device of claim 16, wherein the circuit board includes a chip, and wherein the circuit board includes conductive paths between the chip and the array of bonding pads.

18. The device of claim 15, wherein the one or more transistors includes a transistor associated with the display unit, wherein the associated internal interconnect is coupled with a first terminal of the transistor, and the transistor has a second terminal coupled with an electrode of the display unit.

19. A device comprising:
a display including a first display unit;
a bonding pad on a non-viewing side of the display;
a circuit board coupled with the bonding pad; and
an internal interconnect of the display coupled with the bonding pad.

20. The device of claim 19, further comprising:
a first display unit transistor having a first terminal, a second terminal, and a control terminal, wherein the internal interconnect is coupled with the first terminal, and the second terminal is coupled with an electrode of the first display unit.

21. The device of claim 20, further comprising:
a row driver transistor having an output coupled with the control terminal of the control terminal of the first display unit transistor, the row driver transistor and the first display unit transistor both being between the display unit and the bonding pad.

22. The device of claim 20, wherein the circuit board is a chip-on-flex (COF).
